(19) United States
(12) Patent Application Publication
(10) Pub. No.: US 2025/0362183 A1
(43) Pub. Date: Nov. 27, 2025

(54) SEMICONDUCTOR DEVICE

(71) Applicant: Mitsubishi Electric Corporation, Tokyo (JP)

(72) Inventors: Kakeru OTSUKA, Tokyo (JP); Yosuke NAKATA, Tokyo (JP); Reona FURUKAWA, Tokyo (JP)

(73) Assignee: Mitsubishi Electric Corporation, Tokyo (JP)

(21) Appl. No.: 19/009,898

(22) Filed: Jan. 3, 2025

(30) Foreign Application Priority Data
May 27, 2024 (JP) 2024-085469

(51) Int. Cl. G01K 7/01; H10D 80/20; H10D 84/00; H10D 89/60

(52) U.S. Cl. CPC G01K 7/015; H10D 80/231; H10D 89/60; H10D 84/161

(57) ABSTRACT

A semiconductor device includes a semiconductor substrate, a temperature sensing diode provided on the semiconductor substrate, and a protective diode provided on the semiconductor substrate and connected in inverse parallel to the temperature sensing diode, wherein the temperature sensing diode includes a first anode layer that is a p-type semiconductor layer, and a first cathode layer that is adjacent to the first anode layer in plan view and is an n-type semiconductor layer, the protective diode includes a second anode layer that is a p-type semiconductor layer, and a second cathode layer that is adjacent to the second anode layer in plan view and is an n-type semiconductor layer, and a pn junction area of the second anode layer and the second cathode layer in the protective diode is larger than a pn junction area of the first anode layer and the first cathode layer in the temperature sensing diode.

### BACKGROUND

### Field

The present disclosure relates to a semiconductor device.

### Background

WO 2021/059881 A discloses a semiconductor device including a protective diode unit and a temperature sensing unit. The protective diode unit includes a diode PN junction of which is connected in a direction being inverse parallel relative to a direction of PN junction of a diode of the temperature sensing unit. The diode of the protective diode unit may have the same design as a design of the diode of the temperature sensing unit, except that the direction of the PN junction. The protective diode unit prevents breakdown when an overvoltage or an overcurrent flows in an inverse direction to the temperature sensing unit due to static electricity, or the like.

As disclosed in WO 2021/059881 A, a protective diode is sometimes provided in inverse parallel to a temperature sensing diode for the purpose of protection of the temperature sensing diode mounted on a semiconductor chip. Characteristics of the temperature sensing diode can be adjusted by a thickness of polysilicon or concentration of a diffuse layer. Here, in a case where the polysilicon is made thinner or the concentration of the diffuse layer is made lower, a parameter of the protective diode follows the change. Thus, there is a possibility that electro-static discharge (ESD) withstand capability may degrade due to increase in current density unless an appropriate design is made.

### SUMMARY

The present disclosure has been made to solve the above-described problem and is directed to providing a semiconductor device capable of improving ESD withstand capability of a protective diode.

The features and advantages of the present disclosure may be summarized as follows.

According to an aspect of the present disclosure, a semiconductor device includes a semiconductor substrate; a temperature sensing diode provided on the semiconductor substrate; and a protective diode provided on the semiconductor substrate and connected in inverse parallel to the temperature sensing diode, wherein the temperature sensing diode includes a first anode layer that is a p-type semiconductor layer, and a first cathode layer that is adjacent to the first anode layer in plan view and is an n-type semiconductor layer, the protective diode includes a second anode layer that is a p-type semiconductor layer, and a second cathode layer that is adjacent to the second anode layer in plan view and is an n-type semiconductor layer, and a pn junction area of the second anode layer and the second cathode layer in the protective diode is larger than a pn junction area of the first anode layer and the first cathode layer in the temperature sensing diode.

Other and further objects, features and advantages of the disclosure will appear more fully from the following description.

### BRIEF DESCRIPTION OF DRAWINGS

FIG. 1 is a plan view of a temperature sensing diode and a protective diode according to a first embodiment.

FIG. 2 is a cross-sectional view of the temperature sensing diode and the protective diode according to the first embodiment.

FIG. 3 is a plan view of a temperature sensing diode according to a modification of the first embodiment.

FIG. 4 is a cross-sectional view of a temperature sensing diode and a protective diode according to a second embodiment.

FIG. 5 is a plan view of the temperature sensing diode and a protective diode according to a third embodiment.

FIG. 6 is a plan view of a semiconductor device according to a comparative example of a fourth embodiment.

FIG. 7 is a plan view of a semiconductor device according to the fourth embodiment.

FIG. 8 is a plan view of the temperature sensing diode and a protective diode according to a fifth embodiment.

FIG. 9 is a cross-sectional view of a protective diode according to a sixth embodiment.

FIG. 10 is an enlarged view of FIG. 9.

FIG. 11 is a plan view of a protective diode according to a seventh embodiment.

FIG. 12 is a cross-sectional view of the protective diode according to the seventh embodiment.

FIG. 13 is a plan view of the temperature sensing diode and the protective diode according to an eighth embodiment.

FIG. 14A is a plan view of a protective diode according to a ninth embodiment.

FIGS. 14B to 14H are plan views of protective diodes according to modifications of the ninth embodiment.

FIG. 15 is a plan view of a semiconductor device according to a tenth embodiment.

FIG. 16 is a plan view of a semiconductor device according to a twelfth embodiment.

FIG. 17 is a plan view of a semiconductor device according to a thirteenth embodiment.

### DESCRIPTION OF EMBODIMENTS

A semiconductor device according to each embodiment will be described with reference to the accompanying drawings. Components identical or corresponding to each other are indicated by the same reference characters, and repeated description of them is avoided in some cases.

### First Embodiment

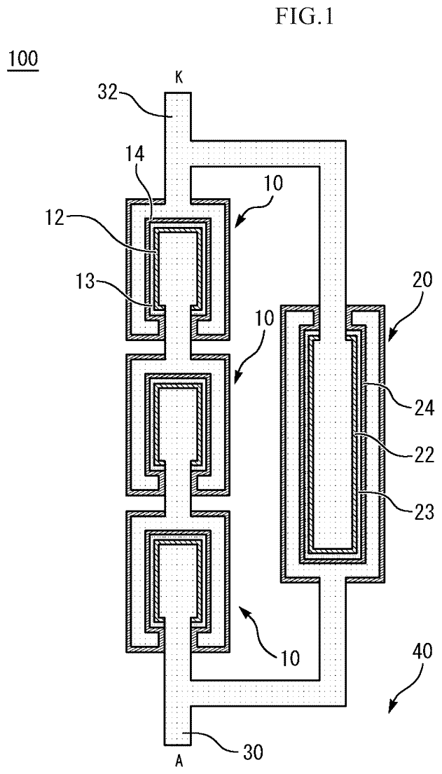

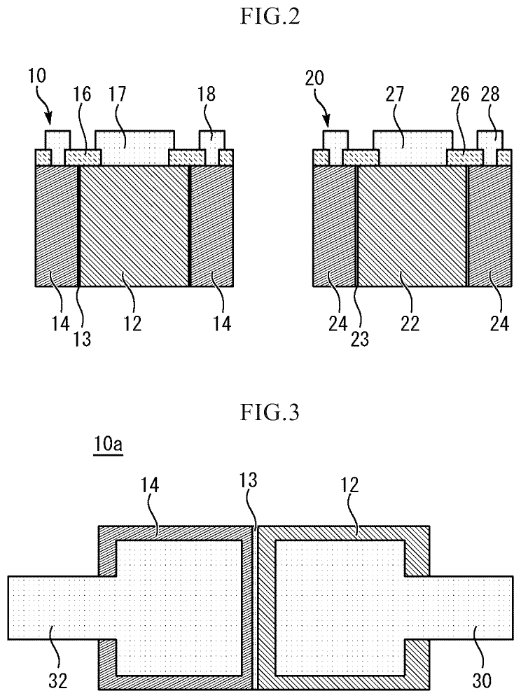

FIG. 1 is a plan view of a temperature sensing diode 10 and a protective diode 20 according to a first embodiment. FIG. 2 is a cross-sectional view of the temperature sensing diode 10 and the protective diode 20 according to the first embodiment. A semiconductor device 100 of the present embodiment includes a semiconductor substrate 40, the temperature sensing diode 10 provided on the semiconductor substrate 40, and the protective diode 20 provided on the semiconductor substrate 40 and connected in inverse parallel to the temperature sensing diode 10. The semiconductor device 100 is, for example, an insulated gate bipolar transistor (IGBT).

The temperature sensing diode 10 includes an anode layer 12 that is a p-type semiconductor layer, and a cathode layer 14 that is adjacent to the anode layer 12 in plan view and is an n-type semiconductor layer. The protective diode 20 includes an anode layer 22 that is a p-type semiconductor layer, and a cathode layer 24 that is adjacent to the anode layer 22 in plan view and is an n-type semiconductor layer. The anode layer 12, 22 is a p-type diffuse layer, and the cathode layer 14, 24 is an n-type diffuse layer. The anode layer 12, 22 and the cathode layer 14, 24 are formed with, for example, polysilicon.

In the semiconductor device 100, three temperature sensing diodes 10 are connected in series. The protective diode 20 is connected in inverse parallel to a series circuit formed by the plurality of temperature sensing diodes 10. The number of the temperature sensing diodes 10 and the number of the protective diodes 20 provided in the semiconductor device 100 are not limited.

An electrode 17 is provided on the anode layer 12 of the temperature sensing diode 10, and an electrode 18 is provided on the cathode layer 14. An insulating film 16 is provided between the electrodes 17 and 18. In the plurality of temperature sensing diodes 10, the electrode 17 and the electrode 18 of the adjacent temperature sensing diodes 10 are electrically connected. Further, also in the plurality of temperature sensing diodes 10, the electrode 17 of the temperature sensing diode 10 that is the closest to an anode wiring 30 side is electrically connected to the anode wiring 30. In the plurality of temperature sensing diodes 10, the electrode 18 of the temperature sensing diode 10 that is the closest to a cathode wiring 32 side is electrically connected to the cathode wiring 32.

An electrode 27 is provided on the anode layer 22 of the protective diode 20, and an electrode 28 is provided on the cathode layer 24. An insulating film 26 is provided between the electrodes 27 and 28. The electrode 27 is electrically connected to the cathode wiring 32. The electrode 28 is electrically connected to the anode wiring 30. In a case where the plurality of protective diodes 20 are connected in series, the electrode 27 and the electrode 28 of the adjacent protective diodes 20 are electrically connected in a similar manner to the temperature sensing diode 10.

A pn junction surface 13 is formed at a portion at which the anode layer 12 is in contact with the cathode layer 14 in the temperature sensing diode 10. A pn junction surface 23 is formed at a portion at which the anode layer 22 is in contact with the cathode layer 24 in the protective diode 20. The pn junction surface 13, 23 may be, for example, perpendicular to or oblique to an upper surface of the semiconductor substrate 40.

In the present embodiment, a pn junction length of the pn junction surface 23 in the protective diode 20 is longer than a pn junction length of the pn junction surface 13 in the temperature sensing diode 10 in plan view. Further, for example, a thickness of a semiconductor layer of the temperature sensing diode 10 is the same as a thickness of a semiconductor layer of the protective diode 20. Thus, a pn junction area of the pn junction surface 23 in the protective diode 20 is larger than a pn junction area of the pn junction surface 13 in the temperature sensing diode 10.

Note that in a case where a plurality of the temperature sensing diodes 10 or the protective diodes 20 are provided, the pn junction area of one protective diode 20 is made larger than the pn junction area of one temperature sensing diode 10.

Effects of the present embodiment will be described next. In the semiconductor device 100, the protective diode 20 is connected in inverse parallel to the temperature sensing diode 10. By this means, in a case where static electricity is applied to the temperature sensing diode 10, a current in an inverse direction flows into the protective diode 20, so that ESD breakdown of the temperature sensing diode 10 can be prevented.

Here, if characteristics of the temperature sensing diode are adjusted, typically, a parameter of the protective diode also follows the adjustment. Thus, in a case where the polysilicon is made thinner, or concentration of the diffuse layer is made lower, there is a possibility that characteristics of the protective diode 20 may change and ESD withstand capability may degrade. Note that the ESD withstand capability indicates withstand capability against static electricity, that is, instantaneous current application.

In contrast, in the present embodiment, the pn junction area of the pn junction surface 23 in the protective diode 20 is larger than the pn junction area of the pn junction surface 13 in the temperature sensing diode 10. If the pn junction area increases, density of a current flowing through the pn junction surface decreases, so that the ESD withstand capability can be improved. By this means, the ESD withstand capability of the protective diode 20 can be made higher than the ESD withstand capability of the temperature sensing diode 10. It is therefore possible to improve the ESD withstand capability of the protective diode 20, so that it is possible to reliably protect the temperature sensing diode 10.

Further, in the present embodiment, the pn junction length of the protective diode 20 is made longer than the pn junction length of the temperature sensing diode 10. This makes it possible to improve the ESD withstand capability of the protective diode 20 while there is a constraint that the parameter of the protective diode 20 follows the parameter of the temperature sensing diode 10.

Note that as will be described in a second embodiment, the pn junction area can be increased also by making the diode thicker. However, in a case where the thickness is changed, there is a possibility that a film formation period may become longer, and a step of forming the protective diode 20 may become longer. In contrast, the pn junction length in plan view can be adjusted without making a process period longer.

The effects of the present embodiment will be described next using experimental results. The ESD withstand capability required in a power device is, for example, equal to or higher than 2.0 kV in a human body model (HBM) method. As a result of an ESD test being implemented on a diode having the pn junction length of 520 μm, there is a case where breakdown occurs at equal to or less than 2.0 kV. In contrast, in a case where the pn junction length is changed to 1988 μm without changing a peripheral structure of the diode, it has been confirmed that breakdown does not occur until 7.0 kV and breakdown occurs at 7.5 kV. Further, in a case where diodes having the pn junction length of 520 μm are connected in series in three stages without changing the peripheral structure of the diodes, it has been confirmed that breakdown does not occur until 2.8 kV and breakdown occurs at 2.9 kV.

Typically, to improve the ESD withstand capability, it is necessary to reduce an energy load on the diode. By increasing the pn junction area, current density per diode can be decreased, and the energy load can be reduced. Further, by increasing stages of the diodes, a voltage per diode can be decreased, and the energy load can be reduced. In the above-described experimental results, while the both have effects in improvement of the ESD withstand capability, the ESD withstand capability can be largely improved particularly by increasing the pn junction area. In this manner, in the present embodiment, by making the pn junction area of one protective diode 20 larger than the pn junction area of one temperature sensing diode 10, the ESD withstand capability of the protective diode 20 can be effectively improved.

FIG. 3 is a plan view of a temperature sensing diode 10a according to a modification of the first embodiment. In the example in FIG. 1, in the temperature sensing diode 10 and the protective diode 20, the cathode layer encloses the anode layer in plan view. The configuration is not limited to this, and in the temperature sensing diode 10 or the protective diode 20, the anode layer may enclose the cathode layer in plan view. Further, as illustrated in FIG. 3, in the temperature sensing diode 10a, the anode layer 12 and the cathode layer 14 may be arranged side by side in plan view. A similar configuration can be employed for the protective diode 20.

The semiconductor substrate 40 may be made with silicon or may be made with a wide bandgap semiconductor. The wide bandgap semiconductor is silicon carbide, gallium nitride-based material or diamond.

These modifications can be appropriately applied to semiconductor devices according to embodiments below. Meanwhile, for the semiconductor devices according to the embodiments below, dissimilarities with the first embodiment will mainly be explained as they have many similarities with the first embodiment.

### Second Embodiment

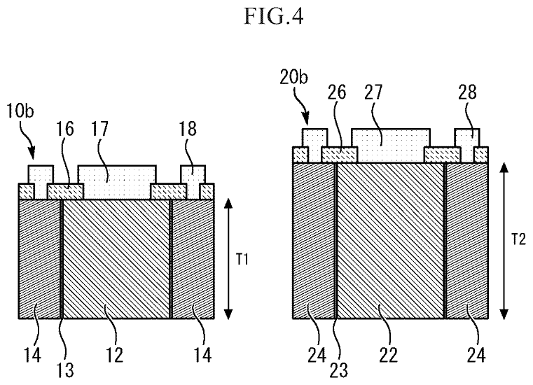

FIG. 4 is a cross-sectional view of a temperature sensing diode 10b and a protective diode 20b according to a second embodiment. The protective diode 20b is thicker than the temperature sensing diode 10b. In other words, T2>T1. By this means, also in the present embodiment, the pn junction area of the protective diode 20b can be made larger than the pn junction area of the temperature sensing diode 10b. Thus, the ESD withstand capability of the protective diode 20 can be made higher than the ESD withstand capability of the temperature sensing diode 10, so that the ESD withstand capability of the protective diode 20 can be improved.

In the present embodiment, the pn junction length of the protective diode 20b in plan view does not have to be made longer. It is therefore possible to reduce an invalid region on the semiconductor substrate 40 while improving the ESD withstand capability of the protective diode 20b.

Note that in plan view, the pn junction length of the protective diode 20b is, for example, the same as the pn junction length of the temperature sensing diode 10b. The present disclosure is not limited to this, and the pn junction length of the protective diode 20b may be longer than the pn junction length of the temperature sensing diode 10b.

### Third Embodiment

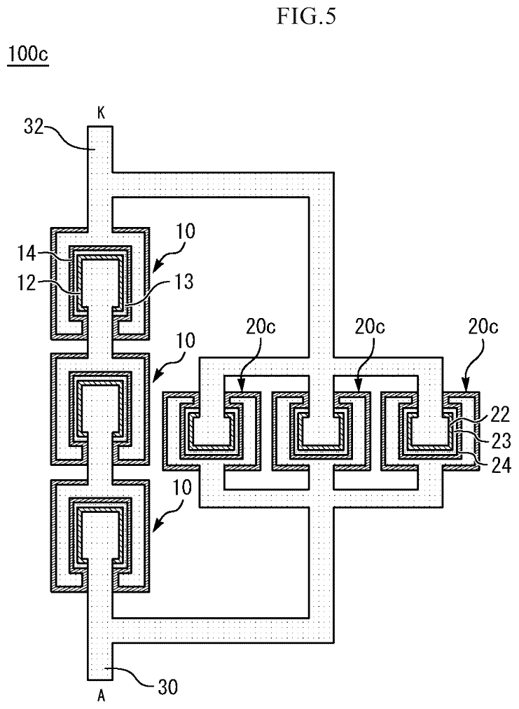

FIG. 5 is a plan view of the temperature sensing diode 10 and a protective diode 20c according to a third embodiment. The present embodiment is different from the first embodiment in that a plurality of protective diodes 20c connected in parallel are provided. Other configurations are similar to the configurations of the first embodiment. Note that also in the present embodiment, the pn junction area of one protective diode 20c is larger than the pn junction area of one temperature sensing diode 10. As a structure in which the pn junction area of the protective diode 20c is made larger, the structure of the first embodiment or the second embodiment can be employed. This similarly applies to embodiments described below.

In the present embodiment, a current flowing through one protective diode 20c can be reduced, so that it is possible to further improve the ESD withstand capability.

### Fourth Embodiment

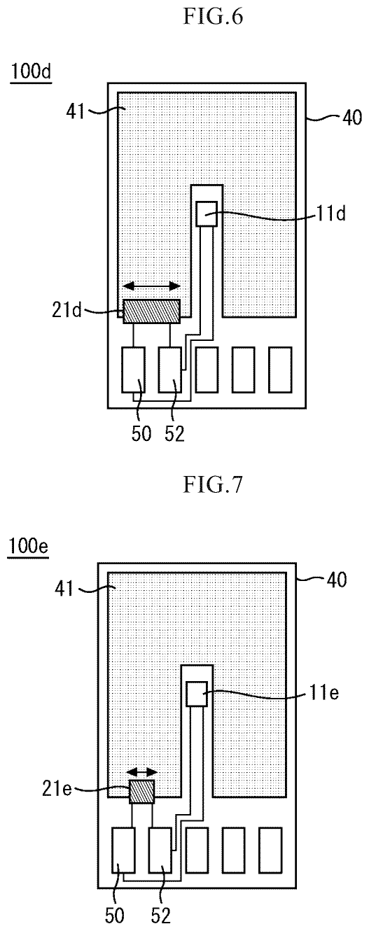

FIG. 6 is a plan view of a semiconductor device 100d according to a comparative example of a fourth embodiment. FIG. 7 is a plan view of a semiconductor device 100e according to the fourth embodiment. In the semiconductor device 100d, 100e, a valid region 41 that is an energized region is provided on the semiconductor substrate 40. In a peripheral portion of the semiconductor substrate 40, an anode pad 50 and a cathode pad 52 are provided. The anode pad 50 is electrically connected to the anode wiring 30, and the cathode pad 52 is electrically connected to the cathode wiring 32.

A temperature sensing diode 11d, 11e is, for example, arranged so as to be enclosed by the valid region 41 and detects a temperature of the valid region 41. The temperature sensing diode 11d, 11e includes a plurality of temperature sensing diodes 10 connected in series. A protective diode unit 21d is, for example, provided adjacent to the anode pad 50 and the cathode pad 52. The protective diode unit 21d includes a plurality of protective diodes 20 connected in series. Note that a similar configuration can be also employed for the semiconductor devices of the first to the third embodiments.

In the protective diode unit 21e in the present embodiment, the number of the protective diodes 20 is smaller than the number of the protective diode units 21d in the comparative example. Thus, an area of the protective diode unit 21e is smaller than an area of the protective diode unit 21d. A region in which the protective diode 20 is provided on the semiconductor substrate 40 becomes an invalid region that does not function as an IGBT. Thus, the invalid region can be reduced in a configuration where the number of the protective diodes 20 is smaller.

The semiconductor device 100e of the present embodiment includes a plurality of temperature sensing diodes 10 connected in series, and a plurality of protective diodes 20 connected in series. The number of the protective diodes 20 may be one. The plurality of temperature sensing diodes 10 and the plurality of protective diodes 20 are connected in inverse parallel. The number of the protective diodes 20 is smaller than the number of the temperature sensing diodes 10. In other words, a configuration as illustrated in FIG. 1 can be employed. In the present embodiment, the number of the protective diodes 20 is small, so that the invalid region can be reduced.

### Fifth Embodiment

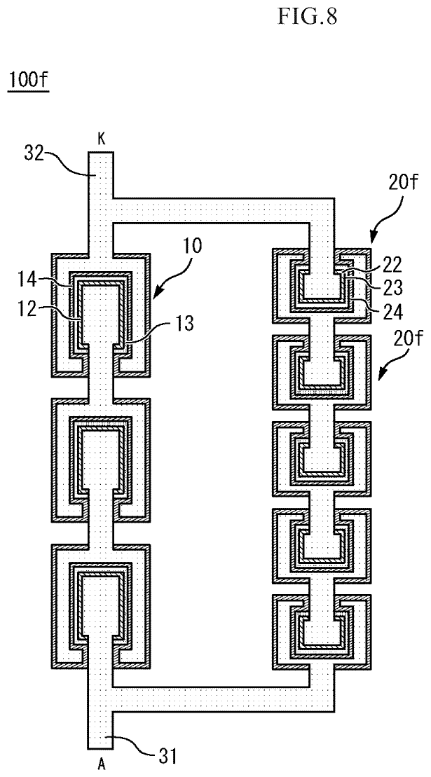

FIG. 8 is a plan view of the temperature sensing diode 10 and a protective diode 20f according to a fifth embodiment. A semiconductor device 100f of the present embodiment includes a plurality of temperature sensing diodes 10 connected in series, and a plurality of protective diodes 20f connected in series. Note that the number of the temperature sensing diodes 10 may be one. The plurality of temperature sensing diodes 10 and the plurality of protective diodes 20f are connected in inverse parallel. The number of the protective diodes 20f is larger than the number of the temperature sensing diodes 10.

In the present embodiment, by increasing the number of stages of the protective diode 20f, the ESD withstand capability of the protective diode 20f can be improved.

### Sixth Embodiment

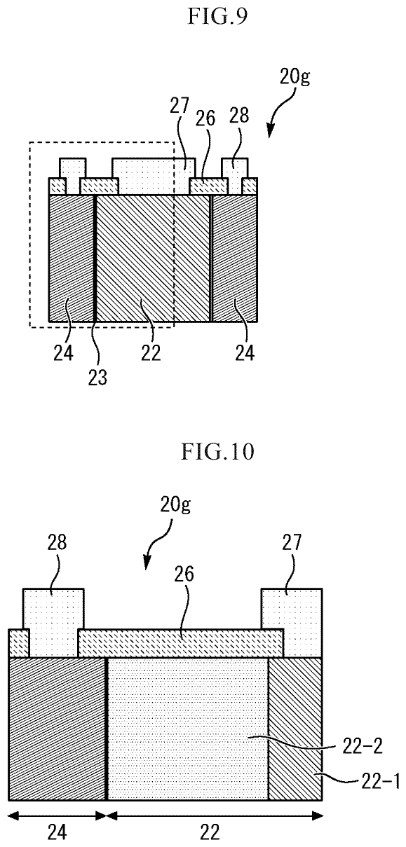

FIG. 9 is a cross-sectional view of a protective diode 20g according to a sixth embodiment. FIG. 10 is an enlarged view of FIG. 9. FIG. 10 illustrates a configuration of a portion enclosed by a dashed line in FIG. 9. The anode layer 22 of the protective diode 20g includes a high-concentration anode layer 22-1 and a low-concentration anode layer 22-2 provided between the high-concentration anode layer 22-1 and the cathode layer 24. In a similar manner, the anode layer 12 of the temperature sensing diode 10 includes a high-concentration anode layer and a low-concentration anode layer provided between the high-concentration anode layer and the cathode layer 14.

By providing the high-concentration anode layers and the low-concentration anode layers in the protective diode 20g and the temperature sensing diode 10, characteristics can be easily adjusted. Note that a structure in which the anode layer includes the high-concentration anode layer and the low-concentration anode layer may be applied to both or only one of the protective diode 20g and the temperature sensing diode 10.

Further, the structure having a high-concentration layer and a low-concentration layer may be applied to the cathode layer instead of the anode layer. In other words, the cathode layer 24 of the protective diode 20g may have a high-concentration cathode layer and a low-concentration cathode layer provided between the high-concentration cathode layer and the anode layer 22. In a similar manner, the cathode layer 14 of the temperature sensing diode 10 may have a high-concentration cathode layer and a low-concentration cathode layer provided between the high-concentration cathode layer and the anode layer 12. Also in this case, characteristics can be easily adjusted. Note that the structure in which the cathode layer has the high-concentration cathode layer and the low-concentration cathode layer may be applied to both or only one of the protective diode 20g and the temperature sensing diode 10.

Further, the high-concentration layer and the low-concentration layer may be applied to both the anode layer and the cathode layer. In other words, the anode layer 22 of the protective diode 20g may have the high-concentration anode layer 22-1 and the low-concentration anode layer 22-2, and the cathode layer 24 may have the high-concentration cathode layer and the low-concentration cathode layer. A similar configuration can be also applied to the temperature sensing diode 10. The structure having the high-concentration layer and the low-concentration layer may be applied to any of the anode layer and the cathode layer of the protective diode 20g and the temperature sensing diode 10.

### Seventh Embodiment

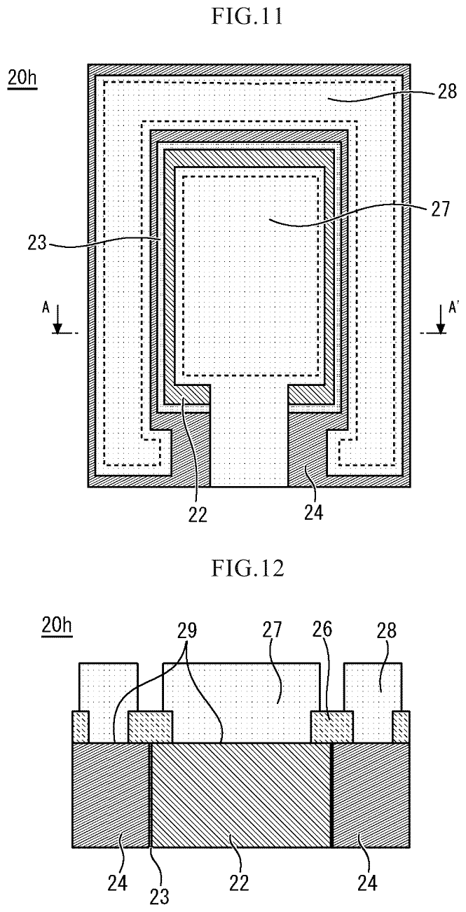

FIG. 11 is a plan view of a protective diode 20h according to a seventh embodiment. FIG. 12 is a cross-sectional view of the protective diode 20h according to the seventh embodiment. FIG. 12 is a cross-sectional view obtained by cutting FIG. 11 along a line A-A′. The protective diode 20h includes the electrode 27 provided on the anode layer 22 and the electrode 28 provided on the cathode layer 24. In plan view, 50% or more of the area of the anode layer 22 is in contact with the electrode 27. Further, in plan view, 50% or more of the area of the cathode layer 24 is in contact with the electrode 28. A region enclosed by a dashed line in FIG. 11 is a region 29 in which the electrode 27, 28 illustrated in FIG. 12 is in contact with the anode layer 22 or the cathode layer 24. In the present embodiment, as one example, approximately 60% of the area of the anode layer 22 is in contact with the electrode 27, and approximately 60% of the area of the cathode layer 24 is in contact with the electrode 28.

By increasing the area that is in contact with the electrode in the protective diode 20h, it is possible to reduce resistance and improve ESD withstand capability. Note that it is only necessary that 50% or more of the area of at least one of the anode layer 22 or the cathode layer 24 is in contact with the electrode.

### Eighth Embodiment

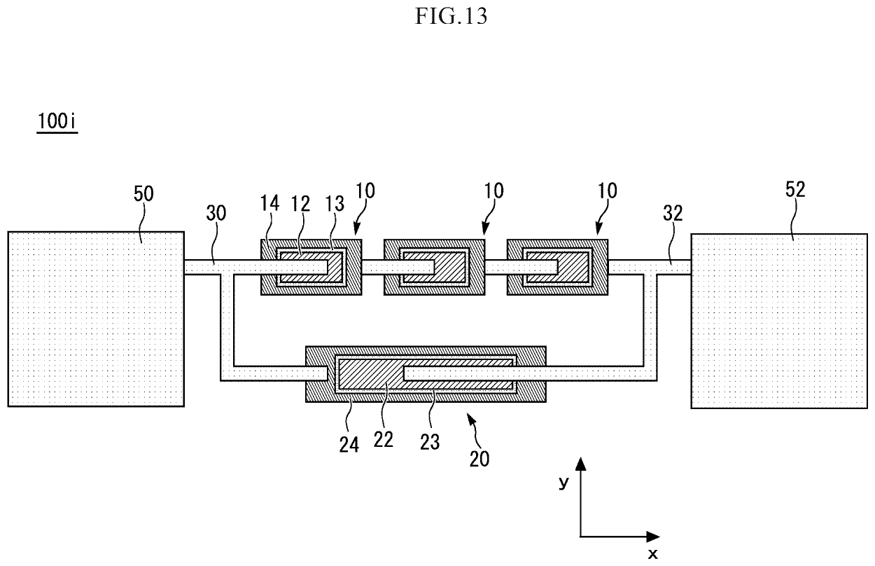

FIG. 13 is a plan view of the temperature sensing diode 10 and the protective diode 20 according to an eighth embodiment. A semiconductor device 100i of the present embodiment includes the anode pad 50 connected to the anode layer 12 of the temperature sensing diode 10, and the cathode pad 52 connected to the cathode layer 14. The temperature sensing diode 10 and the protective diode 20 fit into a region between the anode pad 50 and the cathode pad 52 in plan view.

In an x direction from the anode pad 50 toward the cathode pad 52, that is, in a longitudinal direction of the protective diode 20, the temperature sensing diode 10 and the protective diode 20 may fit into the region between the anode pad 50 and the cathode pad 52. Further, in a y direction orthogonal to the x direction, the temperature sensing diode 10 and the protective diode 20 may fit into a width of the anode pad 50 or the cathode pad 52.

This can reduce an invalid region. Note that only one of the temperature sensing diode 10 or the protective diode 20 may fit into the region between the anode pad 50 and the cathode pad 52 in plan view.

### Ninth Embodiment

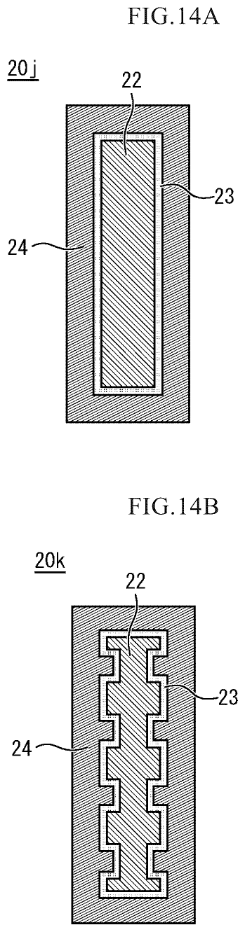

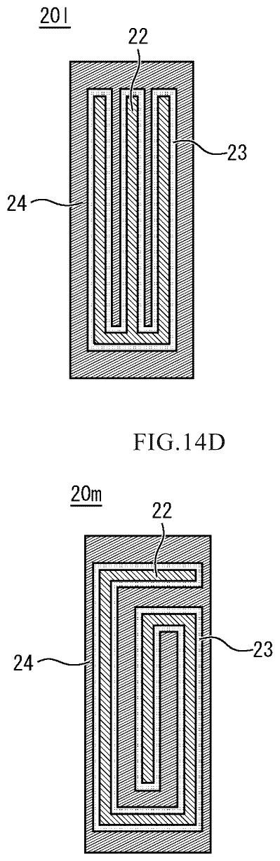

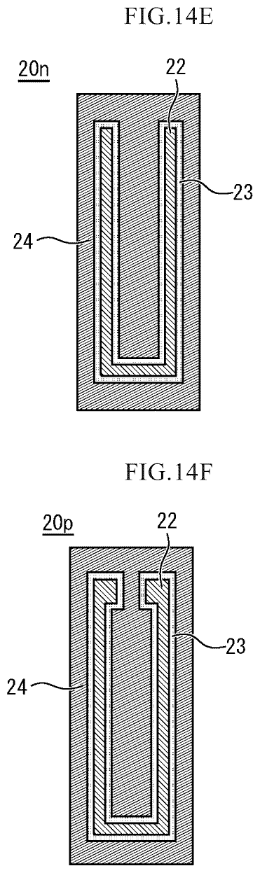

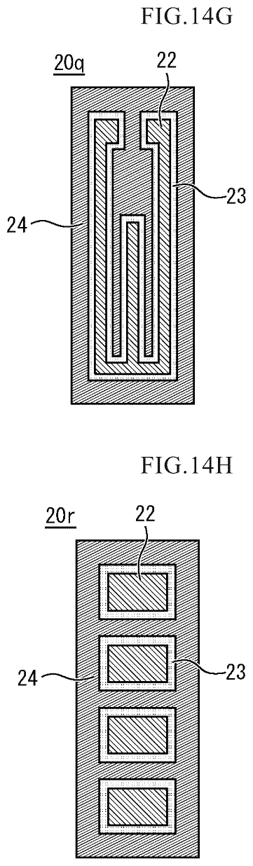

FIG. 14A is a plan view of a protective diode 20j according to a ninth embodiment. FIGS. 14B to 14H are plan views of protective diodes according to modifications of the ninth embodiment. As illustrated in FIG. 14A, the pn junction surface 23 of the protective diode 20j may have a rectangular shape or a square shape in plan view. The shape is not limited to this, and the pn junction surface 23 may have a polygonal shape in plan view.

Further, as illustrated in FIG. 14B, the pn junction surface 23 of a protective diode 20k may have a shape having irregularities. As illustrated in FIG. 14C, the pn junction surface 23 of a protective diode 201 may have a fork shape. As illustrated in FIG. 14D, the pn junction surface 23 of a protective diode 20m may have a curling shape.

As illustrated in FIG. 14E and FIG. 14F, the pn junction surface 23 of a protective diode 20n, 20p may have a U shape. Further, as the pn junction surface 23 having a fork shape, a shape as in the pn junction surface 23 of a protective diode 20q in FIG. 14G can be employed. Still further, as in a protective diode 20r in FIG. 14H, a plurality of anode layers 22 may be provided inside one cathode layer 24.

According to these shapes of the pn junction surface 23, it is possible to increase the area of the pn junction surface 23 while preventing increase in size of the protective diode 20. It is therefore possible to improve the ESD withstand capability of the protective diode 20. Note that positions of the anode layer 22 and the cathode layer 24 illustrated in FIG. 14A to FIG. 14H may be replaced with each other.

### Tenth Embodiment

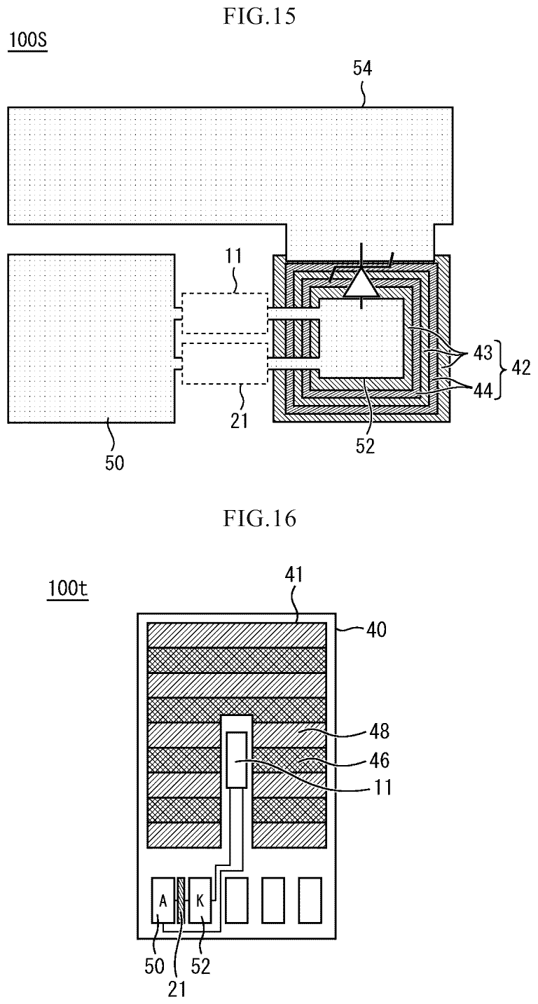

FIG. 15 is a plan view of a semiconductor device 100s according to a tenth embodiment. A temperature sensing diode unit 11 illustrated in FIG. 15 includes one or more temperature sensing diodes 10 connected in series. A protective diode unit 21 includes a plurality of protective diodes 20 connected in series or in parallel. The semiconductor device 100s includes a zener diode 42 connected between the cathode pad 52 and a main electrode 54 of the semiconductor device 100s. The main electrode 54 is an energization electrode of a principal current on a principal surface of the semiconductor device 100s and is, for example, an emitter electrode.

The zener diode 42 includes an anode layer 43 that encloses the cathode pad 52 in plan view and a cathode layer 44 that encloses the anode layer 43 in plan view. A plurality of anode layers 43 and a plurality of cathode layers 44 may be alternately provided. In the zener diode 42, a conductive type of a semiconductor layer in an innermost circumference needs to match a conductive type of a semiconductor layer in an outermost circumference. Note that a structure of the zener diode 42 is not limited to that illustrated in FIG. 15.

In the present embodiment, the zener diode 42 can protect between the cathode and the main electrode, so that reliability can be further improved.

### Eleventh Embodiment

A semiconductor device on which the temperature sensing diode 10 and the protective diode 20 are mounted may be a power semiconductor device. This can improve reliability of the power semiconductor device.

### Twelfth Embodiment

FIG. 16 is a plan view of a semiconductor device 100t according to a twelfth embodiment.

A reverse-conducting (RC)-IGBT may be formed on the semiconductor substrate 40. The temperature sensing diode unit 11 of the present embodiment is arranged adjacent to an IGBT region 46 and a diode region 48 of the RC-IGBT. By this means, temperatures of both the IGBT region 46 and the diode region 48 can be detected.

### Thirteenth Embodiment

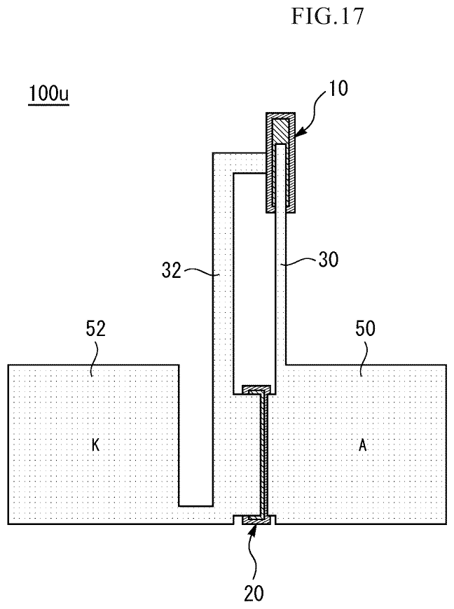

FIG. 17 is a plan view of a semiconductor device 100u according to a thirteenth embodiment. In the semiconductor device 100u, the anode layer 12 of the temperature sensing diode 10 is electrically connected to the anode pad 50 via the anode wiring 30. Further, the cathode layer 14 of the temperature sensing diode 10 is electrically connected to the cathode pad 52 via the cathode wiring 32. The protective diode 20 is arranged between the anode pad 50 and the cathode wiring 32. The arrangement of the protective diode 20 is not limited to this, and the protective diode 20 may be arranged between the anode wiring 30 and the cathode wiring 32 or between the anode wiring 30 and the cathode pad 52.

By arranging the protective diode 20 as described above, a region on the semiconductor substrate 40 can be effectively utilized. In other words, it is possible to make the pn junction length longer while preventing reduction of an effective area due to arrangement of the protective diode 20.

Meanwhile, technical features explained in each embodiment may be appropriately combined to use.

Hereinafter, various aspects of the present disclosure will be collectively described as appendixes.

### APPENDIX 1

A semiconductor device comprising:
a semiconductor substrate;
a temperature sensing diode provided on the semiconductor substrate; and
a protective diode provided on the semiconductor substrate and connected in inverse parallel to the temperature sensing diode, wherein
the temperature sensing diode includes a first anode layer that is a p-type semiconductor layer, and a first cathode layer that is adjacent to the first anode layer in plan view and is an n-type semiconductor layer,
the protective diode includes a second anode layer that is a p-type semiconductor layer, and a second cathode layer that is adjacent to the second anode layer in plan view and is an n-type semiconductor layer, and
a pn junction area of the second anode layer and the second cathode layer in the protective diode is larger than a pn junction area of the first anode layer and the first cathode layer in the temperature sensing diode.

### APPENDIX 2

The semiconductor device according to appendix 1, wherein a pn junction length of the second anode layer and the second cathode layer in the protective diode is longer than a pn junction length of the first anode layer and the first cathode layer in the temperature sensing diode in plan view.

### APPENDIX 3

The semiconductor device according to appendix 1, wherein the protective diode is thicker than the temperature sensing diode.

### APPENDIX 4

The semiconductor device according to any one of appendixes 1 to 3, comprising a plurality of the protective diodes connected in parallel.

### APPENDIX 5

The semiconductor device according to any one of appendixes 1 to 3, comprising:
a plurality of the temperature sensing diodes connected in series; and
one protective diode or a plurality of the protective diodes connected in series, wherein
the plurality of temperature sensing diodes and the one or the plurality of protective diodes are connected in inverse parallel, and
the number of the protective diodes is smaller than the number of the temperature sensing diodes.

### APPENDIX 6

The semiconductor device according to any one of appendixes 1 to 3, comprising:
one temperature sensing diode or a plurality of the temperature sensing diodes connected in series; and
a plurality of the protective diodes connected in series, wherein
the one or the plurality of temperature sensing diodes and the plurality of protective diodes are connected in inverse parallel, and
the number of the protective diodes is larger than the number of the temperature sensing diodes.

### APPENDIX 7

The semiconductor device according to any one of appendixes 1 to 6, wherein
the first anode layer of the temperature sensing diode includes:
   a first high-concentration anode layer; and
   a first low-concentration anode layer provided between the first high-concentration anode layer and the first cathode layer.

### APPENDIX 8

The semiconductor device according to any one of appendixes 1 to 7, wherein
the first cathode layer of the temperature sensing diode includes:
   a first high-concentration cathode layer; and
   a first low-concentration cathode layer provided between the first high-concentration cathode layer and the first anode layer.

### APPENDIX 9

The semiconductor device according to any one of appendixes 1 to 8, wherein
the second anode layer of the protective diode includes:
   a second high-concentration anode layer; and
   a second low-concentration anode layer provided between the second high-concentration anode layer and the second cathode layer.

### APPENDIX 10

The semiconductor device according to any one of appendixes 1 to 9, wherein
the second cathode layer of the protective diode includes:
   a second high-concentration cathode layer; and
   a second low-concentration cathode layer provided between the second high-concentration cathode layer and the second anode layer.

### APPENDIX 11

The semiconductor device according to any one of appendixes 1 to 10, comprising:
an anode electrode provided on the second anode layer of the protective diode; and
a cathode electrode provided on the second cathode layer of the protective diode,
wherein 50% or more of an area of the second anode layer or the second cathode layer is in contact with the anode electrode or the cathode electrode in plan view.

### APPENDIX 12

The semiconductor device according to any one of appendixes 1 to 11, comprising:
an anode pad connected to the first anode layer of the temperature sensing diode; and
a cathode pad connected to the first cathode layer of the temperature sensing diode,
wherein the temperature sensing diode or the protective diode fits into a region between the anode pad and the cathode pad in plan view.

### APPENDIX 13

The semiconductor device according to appendix 12, wherein the temperature sensing diode and the protective diode fit into the region between the anode pad and the cathode pad in plan view.

### APPENDIX 14

The semiconductor device according to any one of appendixes 1 to 13, wherein a pn junction surface of the second anode layer and the second cathode layer in the protective diode has a shape having irregularities, a fork shape or a curling shape in plan view.

### APPENDIX 15

The semiconductor device according to any one of appendixes 1 to 11, comprising:
an anode pad connected to the first anode layer of the temperature sensing diode;
a cathode pad connected to the first cathode layer of the temperature sensing diode; and
a zener diode connected between the cathode pad and a main electrode of the semiconductor device.

### APPENDIX 16

The semiconductor device according to any one of appendixes 1 to 15, wherein the semiconductor device is a power semiconductor device.

### APPENDIX 17

The semiconductor device according to any one of appendixes 1 to 16, wherein
an RC-IGBT is formed on the semiconductor substrate, and
the temperature sensing diode is arranged adjacent to an IGBT region and a diode region of the RC-IGBT.

### APPENDIX 18

The semiconductor device according to any one of appendixes 1 to 11, comprising:
an anode pad connected to the first anode layer of the temperature sensing diode via an anode wiring; and
a cathode pad connected to the first cathode layer of the temperature sensing diode via a cathode wiring,
wherein the protective diodes is arranged between the anode pad and the cathode wiring, between the anode wiring and the cathode wiring, or between the anode wiring and the cathode pad.

### APPENDIX 19

The semiconductor device any one of appendixes 1 to 18, wherein the semiconductor substrate is made with a wide band gap semiconductor.

### APPENDIX 20

The semiconductor device according to claim 19 wherein the wide band gap semiconductor is silicon carbide, gallium-nitride-based material or diamond.

In a semiconductor device according to the present disclosure, a pn junction area of a second anode layer and a second cathode layer in a protective diode is larger than a pn junction area of a first anode layer and a first cathode layer in a temperature sensing diode. It is therefore possible to improve ESD withstand capability of the protective diode.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-085469, filed on May 27, 2024 including specification, claims, drawings and summary, on which the Convention priority of the present application is based, are incorporated herein by reference in its entirety.

1. A semiconductor device comprising:
a semiconductor substrate;
a temperature sensing diode provided on the semiconductor substrate; and
a protective diode provided on the semiconductor substrate and connected in inverse parallel to the temperature sensing diode, wherein
the temperature sensing diode includes a first anode layer that is a p-type semiconductor layer, and a first cathode layer that is adjacent to the first anode layer in plan view and is an n-type semiconductor layer,
the protective diode includes a second anode layer that is a p-type semiconductor layer, and a second cathode layer that is adjacent to the second anode layer in plan view and is an n-type semiconductor layer, and
a pn junction area of the second anode layer and the second cathode layer in the protective diode is larger than a pn junction area of the first anode layer and the first cathode layer in the temperature sensing diode.

2. The semiconductor device according to claim 1, wherein a pn junction length of the second anode layer and the second cathode layer in the protective diode is longer than a pn junction length of the first anode layer and the first cathode layer in the temperature sensing diode in plan view.

3. The semiconductor device according to claim 1, wherein the protective diode is thicker than the temperature sensing diode.

4. The semiconductor device according to claim 1, comprising a plurality of the protective diodes connected in parallel.

5. The semiconductor device according to claim 1, comprising:
a plurality of the temperature sensing diodes connected in series; and
one protective diode or a plurality of the protective diodes connected in series, wherein
the plurality of temperature sensing diodes and the one or the plurality of protective diodes are connected in inverse parallel, and
the number of the protective diodes is smaller than the number of the temperature sensing diodes.

6. The semiconductor device according to claim 1, comprising:
one temperature sensing diode or a plurality of the temperature sensing diodes connected in series; and
a plurality of the protective diodes connected in series, wherein
the one or the plurality of temperature sensing diodes and the plurality of protective diodes are connected in inverse parallel, and
the number of the protective diodes is larger than the number of the temperature sensing diodes.

7. The semiconductor device according to claim 1, wherein
the first anode layer of the temperature sensing diode includes:
a first high-concentration anode layer; and
a first low-concentration anode layer provided between the first high-concentration anode layer and the first cathode layer.

8. The semiconductor device according to claim 1, wherein
the first cathode layer of the temperature sensing diode includes:
a first high-concentration cathode layer; and
a first low-concentration cathode layer provided between the first high-concentration cathode layer and the first anode layer.

9. The semiconductor device according to claim 1, wherein
the second anode layer of the protective diode includes:
a second high-concentration anode layer; and
a second low-concentration anode layer provided between the second high-concentration anode layer and the second cathode layer.

10. The semiconductor device according to claim 1, wherein
the second cathode layer of the protective diode includes:
a second high-concentration cathode layer; and
a second low-concentration cathode layer provided between the second high-concentration cathode layer and the second anode layer.

11. The semiconductor device according to claim 1, comprising:
an anode electrode provided on the second anode layer of the protective diode; and
a cathode electrode provided on the second cathode layer of the protective diode,
wherein 50% or more of an area of the second anode layer or the second cathode layer is in contact with the anode electrode or the cathode electrode in plan view.

12. The semiconductor device according to claim 1, comprising:
an anode pad connected to the first anode layer of the temperature sensing diode; and
a cathode pad connected to the first cathode layer of the temperature sensing diode,
wherein the temperature sensing diode or the protective diode fits into a region between the anode pad and the cathode pad in plan view.

13. The semiconductor device according to claim 12, wherein the temperature sensing diode and the protective diode fit into the region between the anode pad and the cathode pad in plan view.

14. The semiconductor device according to claim 1, wherein a pn junction surface of the second anode layer and the second cathode layer in the protective diode has a shape having irregularities, a fork shape or a curling shape in plan view.

15. The semiconductor device according to claim 1, comprising:
an anode pad connected to the first anode layer of the temperature sensing diode;
a cathode pad connected to the first cathode layer of the temperature sensing diode; and
a zener diode connected between the cathode pad and a main electrode of the semiconductor device.

16. The semiconductor device according to claim 1, wherein the semiconductor device is a power semiconductor device.

17. The semiconductor device according to claim 1, wherein
an RC-IGBT is formed on the semiconductor substrate, and
the temperature sensing diode is arranged adjacent to an IGBT region and a diode region of the RC-IGBT.

18. The semiconductor device according to claim 1, comprising:
an anode pad connected to the first anode layer of the temperature sensing diode via an anode wiring; and
a cathode pad connected to the first cathode layer of the temperature sensing diode via a cathode wiring,
wherein the protective diodes is arranged between the anode pad and the cathode wiring, between the anode wiring and the cathode wiring, or between the anode wiring and the cathode pad.

19. The semiconductor device according to claim 1, wherein the semiconductor substrate is made with a wide band gap semiconductor.

20. The semiconductor device according to claim 19 wherein the wide band gap semiconductor is silicon carbide, gallium-nitride-based material or diamond.
